(19) United States
(12) Patent Application Publication
(10) Pub. No.: US 2004/0067440 A1
(43) Pub. Date: Apr. 8, 2004

(54) Actinic energy ray-curable resin, photocurable and thermosetting resin composition containing the same, and cured products thereof

(76) Inventors: Shoji Minegishi, Iruma-shi (JP); Yuta Ogawa, Shiki-shi (JP)

Correspondence Address: RADER FISHMAN & GRAUER PLLC, LION BUILDING, 1233 20TH STREET N.W., SUITE 501, WASHINGTON, DC, 20036, US

(21) Appl. No.: 10/665,009

(22) Filed: Sep. 22, 2003

Related U.S. Application Data
(63) Continuation of application No. PCT/JP02/02790, filed on Mar. 22, 2002.

(30) Foreign Application Priority Data
Mar. 23, 2001 (JP) 2001-85921

(51) Int. Cl. G03F 7/038; G03F 7/027; C08F 299/02; C08G 59/00; C09D 167/07; C09D 5/25; C08G 59/14; C08L 63/00

(52) U.S. Cl. 430/280.1; 430/285.1; 430/18; 430/311; 522/100; 522/102; 522/103

(57) ABSTRACT

An actinic energy ray-curable resin is obtained by reacting (c) an epihalohydrin with hydroxyl groups of a linear epoxy resin (A′) which is a product of the polyaddition reaction of (a) a bifunctional hydrogenated bisphenolic epoxy compound with (b) a compound having at least two carboxyl groups in its molecule to obtain a polynuclear epoxy resin (A″) having epoxy groups in its terminal and side chain and further reacting (d) an unsaturated monocarboxylic acid with an epoxy group of the polynuclear epoxy resin (A″) to introduce a photopolymerizable unsaturated group therein and further reacting (e) a polybasic acid anhydride with a hydroxyl group of the polynuclear epoxy resin to introduce a carboxyl group therein. A photocurable and thermosetting resin composition capable of being developed with an aqueous alkaline solution is obtained by mixing this actinic energy ray-curable resin with a photopolymerization initiator, a diluent, and a polyfunctional epoxy compound. The resultant photocurable and thermosetting resin composition is useful as a solder resist for a printed circuit board, interlaminar insulating materials for a multi-layer printed circuit board, and the like.

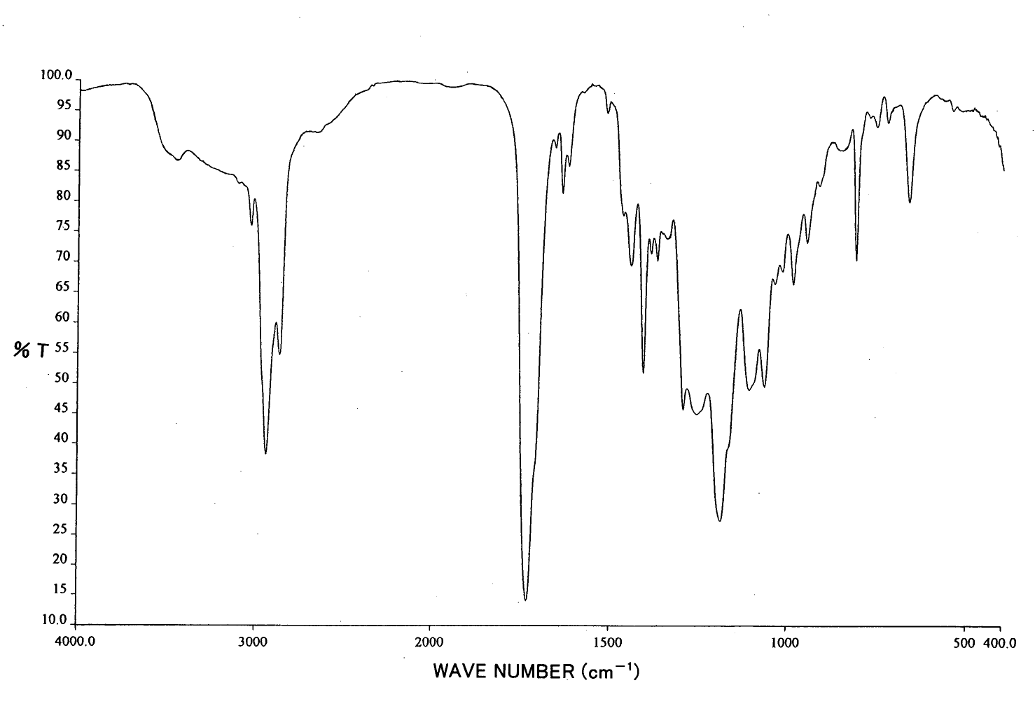

### CROSS-REFERENCE TO RELATED APPLICATION

This is a continuation of Application PCT/JP02/02790, filed Mar. 22, 2002, now abandoned.

### BACKGROUND OF THE INVENTION

1. Field of the Invention

This invention relates to a linear actinic energy ray-curable resin containing a photopolymerizable unsaturated bond and a carboxyl group, particularly relates to a linear actinic energy ray-curable resin containing regularly repeating cyclohexene rings, which is soluble in an alkaline solution. This invention further relates to an alkali-developable, photocurable and thermosetting resin composition using the actinic energy ray-curable resin mentioned above and a cured product thereof, more particularly relates to a liquid, alkali-developable, photocurable and thermosetting resin composition which is suitable for use in various applications, particularly for use as permanent masks for printed circuit boards, interlaminar insulating layers for multi-layer circuit boards, and the like and capable of forming a cured film exhibiting low dielectric properties and excelling in adhesiveness, resistance to electroless plating, electrical properties, flexibility, resistance to moisture absorption, and resistance to PCT (pressure cooker) by means of a procedure comprising the steps of irradiating a coating film of the composition with actinic energy rays, then developing the exposed film with a dilute aqueous alkaline solution, thereby forming an image on the film, and finally curing the film by irradiation with actinic energy rays and subsequent heating, or by heating and subsequent irradiation with actinic energy rays, or by heating and a cured film-forming technology using the composition mentioned above.

2. Description of the Prior Art

At present, as a solder resist for part of the household grade printed circuit boards and for virtually all the industrial grade printed circuit boards, a liquid developing type solder resist which is irradiated with ultraviolet light and then developed to form an image and thereafter finally cured (finish curing) by heating or exposure to light is adopted from the viewpoint of ensuring highly accurate formation of circuits with high density. Further, with due respect to the problem of environmental safety, a liquid solder resist of the alkali developing type which implements development with a dilute aqueous alkaline solution as a developer has come to play the leading role. As such alkali developing type solder resists using a dilute aqueous alkaline solution, for example, published Japanese Patent Application, JP 61-243869A discloses a solder resist composition comprising a photosensitive resin obtained by addition of an acid anhydride to a reaction product of a novolak type epoxy compound with an unsaturated monobasic acid, a photopolymerization initiator, a diluent, and an epoxy compound, and JP 3-253093A discloses a solder resist composition comprising a photosensitive resin obtained by addition of an acid anhydride to a reaction product of a novolak type epoxy compound with an unsaturated monobasic acid, a photopolymerization initiator, a diluent, a vinyltriazine or a mixture of vinyltriazine with dicyandiamide, and a melamine resin.

Although some material systems are heretofore proposed as a solder resist, the solder resist composition predominantly using the photosensitive resin obtained by addition of an acid anhydride to the reaction product of a novolak type epoxy compound with an unsaturated monobasic acid mentioned above as a photosensitive component is currently used in large quantities in the practical manufacture of printed circuit boards. Such a resin is excellent in photocuring properties and developing properties with an alkaline solution. However, it may not be concluded that the above-mentioned resin has reached a satisfactory level in respect of the balance between the photocuring properties and the flexibility. Moreover, this resin has the drawback of being easy to generate cracks by the thermal shock according to the use aimed at because it tends to cause shrinkage during curing and exhibits low elongation and poor toughness.

Further, in view of high densification of the printed circuit board to cope with the recent trend of electronic devices toward decreasing weight and size, the desirability of producing the solder resist having high performance has been finding growing recognition. Furthermore, the IC packages using a printed circuit board having a solder resist applied thereto and a sealing resin are recently used instead of the IC packages called QFP (quad flat-pack package), SOP (small outline package), etc. which use a lead frame and a sealing resin. These new packages have such structure that metals such as ball-like solder are arranged in an area on one side of a printed circuit board having the solder resist applied thereto, the IC chips are directly connected thereto on the other side by wire bonding or through the medium of the bumps etc., and they are sealed by a sealing resin. They are called by mnemonic names, such as BGA (ball grid array) and CSP (chip scale package). These packages have more pins than other packages such as QFP of the same size, but are easier to miniaturize. Moreover, also in mounting the devices, they realize a low percent defective owing to the self-alignment effect of ball-like solder, and the introduction of these packages is advanced quickly.

In the printed circuit boards having the heretofore commercially available alkali developing type solder resist, however, the PCT resistance which is the long-term reliability test of a package is inferior, which results in exfoliation of a solder resist film. Moreover, another matter which comes into question is the so-called popcorn phenomenon, i.e. the phenomenon that the solder resist absorbs moisture and the absorbed moisture boils within the package during re-flow of the package at the step of mounting of devices and cracks occur in the solder resist film and the circumference thereof inside the package. Such problems in resistance to moisture absorption and long-term reliability are undesirable not only in the case of the above-mentioned mounting technology but also in the products for other uses, such as a solder resist for a usual printed circuit board and an interlaminar insulating layer for a multi-layer circuit board like a build-up board.

### SUMMARY OF THE INVENTION

An object of the present invention, therefore, is to provide an alkali-soluble and actinic energy ray-curable resin which is highly sensitive, abounds in flexibility, and exhibits the well-balanced flexibility and toughness.

A further object of the present invention is to provide a liquid, alkali-developable, photocurable and thermosetting resin composition capable of forming a cured film which keeps or improves such properties as low dielectric properties, adhesiveness, resistance to electroless plating, and electrical properties heretofore required of a solder resist of a printed circuit board and an interlaminar insulating layer of a multi-layer circuit board, particularly excels in such properties as resistance to moisture absorption and PCT (pressure cooker) resistance required of an IC package, and capable of coping with high densification and surface mounting of a printed circuit board, and to provide a cured product obtained therefrom.

To accomplish the objects mentioned above, a first aspect of the present invention provides an actinic energy ray-curable resin obtained by reacting (c) an epihalohydrin with hydroxyl groups of a linear epoxy resin (A′) which is a product of the polyaddition reaction of (a) a bifunctional hydrogenated bisphenolic epoxy compound having a hydrogenation degree of 0.1 to 100% with (b) a compound having at least two carboxyl groups in its molecule, preferably a compound having two carboxyl groups in its molecule, to obtain a polynuclear epoxy resin (A″) having epoxy groups in its terminal and side chain and further reacting (d) an unsaturated monocarboxylic acid with an epoxy group of the polynuclear epoxy resin mentioned above to introduce a photopolymerizable unsaturated group therein and further reacting (e) a polybasic acid anhydride with a hydroxyl group of the polynuclear epoxy resin mentioned above to introduce a carboxyl group therein.

The actinic energy ray-curable resin of the present invention is a polybasic acid anhydride adduct of a linear polynuclear epoxy ester of an unsaturated monocarboxylic acid of the alternating copolymerization type, particularly a polybasic acid anhydride adduct of a linear polynuclear epoxy ester of an unsaturated monocarboxylic acid containing regularly repeating cyclohexene rings and no aromatic ring in its main chain skeleton due to the use of a cyclohexene dicarboxylic acid as a polycarboxylic compound and further containing ester linkages therein. Accordingly, it is photocurable and soluble in an alkaline solution, excels in photocuring properties with a low dose of irradiation, and has the well-balanced flexibility and toughness at a high level.

A second aspect of the present invention provides a photocurable and thermosetting resin composition capable of being developed with an aqueous alkaline solution, characterized by comprising (A) the actinic energy ray-curable resin mentioned above, (B) a photopolymerization initiator, (C) a diluent, and (D) an epoxy compound containing two or more epoxy groups in its molecule (hereinafter referred to as “polyfunctional epoxy compound”).

The photocurable and thermosetting resin composition of the present invention containing the actinic energy ray-curable resin mentioned above as a photocuring component excels in the photocuring properties, the developing properties with an alkaline solution, and adhesiveness to a substrate and gives a cured product excelling in such properties as low dielectric properties, water resistance, resistance to electroless plating, resistance to chemicals, electrical insulating properties, flexibility, and PCT resistance. Accordingly, the composition is useful as coating materials, printing ink, adhesives, various resist materials, and materials for the manufacture of color filters, and particularly advantageously usable as a solder resist for a printed circuit board such as a flexible board and a tab board, and interlaminar insulating layers for a multi-layer printed circuit board.

Although the compounding ratios of the components are not limited to particular ones, it is desirable that the photopolymerization initiator (B) be in the range of 0.1 to 25 parts by weight, preferably 0.5 to 20 parts by weight, the diluent (C) be in the range of 10 to 60 parts by weight, preferably 15 to 50 parts by weight, the polyfunctional epoxy compound (D) be in the range of 10 to 100 parts by weight, and if need be, it is desirable to use (E) an epoxy curing catalyst in an amount of 0.1 to 20 parts by weight, respectively based on 100 parts by weight of the actinic energy ray-curable resin (A) mentioned above. In accordance with a preferred embodiment which gives lower dielectric properties, the composition further contains (F) a spherical porous filler having an average particle diameter of 1 to 10 μm. The composition may contain (G) an actinic energy ray-curable resin other than the actinic energy ray-curable resin (A) mentioned above, (H) an epoxidized polybutadiene, (I) spherical urethane beads, etc. in amounts not so large as to impair the effects of the present invention.

The photocurable and thermosetting resin composition of the present invention may be used in the form of liquid or in the form of a dry film and may be advantageously usable in various fields, particularly in the formation of an interlaminar insulating layer and a solder resist for a printed circuit board.

Accordingly, in accordance with a third aspect of the present invention, there is provided a cured product obtained by curing the photocurable and thermosetting resin composition mentioned above by irradiation with actinic energy rays and/or heating. In accordance with its preferred embodiment, there is provided a printed circuit board having an interlaminar insulating layer and/or a solder resist layer formed from the photocurable and thermosetting resin composition mentioned above.

### BRIEF DESCRIPTION OF THE DRAWING

The single FIGURE is a graph showing the infrared absorption spectrum of the actinic energy ray-curable resin obtained in Synthesis Example 1.

### DETAILED DESCRIPTION OF THE INVENTION

The present inventors, after pursuing a diligent study to solve the problems mentioned above, have found that an alkali-soluble, actinic energy ray-curable resin obtained by reacting an epihalohydrin (c) with alcoholic hydroxyl groups of a linear epoxy resin (A′) which is a product of the polyaddition reaction of (a) a bifunctional hydrogenated bisphenolic epoxy compound having a hydrogenation degree of 0.1 to 100% with (b) a compound having at least two carboxyl groups in its molecule, particularly a linear epoxy resin (A′) of the alternating copolymerization type containing regularly repeating cyclohexene rings through the medium of ester linkages and no aromatic ring in its main chain skeleton obtained by using a hydrogenated bisphnol A diglycidyl ether and a cyclohexene dicarboxylic acid, to obtain a polynuclear epoxy resin (A″) having epoxy groups in its terminal and side chain and further reacting (d) an unsaturated monocarboxylic acid with an epoxy group of the polynuclear epoxy resin mentioned above to introduce a photopolymerizable unsaturated group therein and further reacting (e) a polybasic acid anhydride with a hydroxyl group of the polynuclear epoxy resin mentioned above to introduce a carboxyl group therein, is high sensitive and possesses toughness because it has no aromatic ring and further found that the resin composition containing such an actinic energy ray-curable resin as a photocuring component gives a cured product excelling in such properties as low dielectric properties, adhesiveness, resistance to electroless plating, electrical properties, flexibility, resistance to moisture absorption, and PCT (pressure cooker) resistance. As a result, the present invention has been perfected.

Specifically, the actinic energy ray-curable resin of the present invention has a photopolymerizable unsaturated group introduced by reacting an unsaturated monocarboxylic acid with the polynuclear epoxy resin (A″) mentioned above and a carboxyl group introduced by further reacting a polybasic acid anhydride therewith to impart photocuring properties and developing properties with an alkaline solution. Further, since the resin has the linear structure containing regularly repeating cyclohexene rings, its cured product excels in such properties as low dielectric properties, adhesiveness to a substrate, resistance to electroless plating, electrical properties, flexibility, resistance to moisture absorption, and PCT resistance.

Now, the actinic energy ray-curable resin of the present invention and the components of the photocurable and thermosetting composition containing it will be described in detail below. First, the actinic energy ray-curable resin of the present invention will be described below.

The actinic energy ray-curable resin of the present invention is produced by the following steps:

(1) synthesis of a linear epoxy resin (A′) by the alternating polymerization of (a) a bifunctional hydrogenated bisphenolic epoxy compound having a hydrogenation degree of 0.1 to 100% (hereinafter referred to as “hydrogenated bisphenolic epoxy compound”) and (b) a compound having at least two carboxyl groups in its molecule (hereinafter referred to as “polycarboxylic compound”), particularly a compound having two carboxyl groups in its molecule (hereinafter referred to as “dicarboxylic acid”),

(2) synthesis of a polynuclear epoxy resin (A″) having epoxy groups in its terminal and side chain by the reaction of (c) an epihalohydrin with alcoholic hydroxyl groups of the linear epoxy resin (A′) mentioned above,

(3) synthesis of an epoxy ester of an unsaturated monocarboxylic acid by reacting (d) an unsaturated group-containing monocarboxylic acid with an epoxy group of the polynuclear epoxy resin (A″) mentioned above, and

(4) synthesis of a carboxyl group-containing actinic energy ray-curable resin by reacting (e) a polybasic acid anhydride with a hydroxyl group of the epoxy ester of an unsaturated monocarboxylic acid mentioned above.

Now, the synthesis of the linear epoxy resin (A′) mentioned above will be described.

First, the linear epoxy resin (A′) is obtained by alternately polymerizing (a) the hydrogenated bisphenolic epoxy compound and (b) the polycarboxylic compound used as the raw materials by using a known catalyst to be described hereinbelow. The linear epoxy resin (A′) obtained may be represented by the following general formula (1), for example.

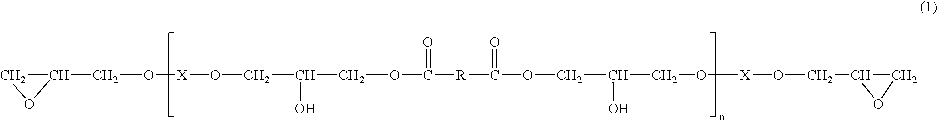

Wherein R represents a polycarboxylic compound residue (or a dicarboxylic acid residue), X represents at least one group represented by the following formulas, and n is an integer of not less than 1, the upper limit thereof being defined by a desired molecular weight of the actinic energy ray-curable resin of the present invention to be described hereinbelow.

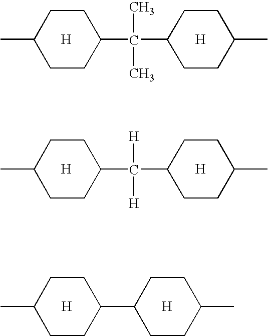

By using the hydrogenated bisphenolic epoxy compound as the other monomer component in the alternating copolymer with the polycarboxylic compound, there is obtained an epoxy resin of which cured product excels in flexibility, low dielectric properties, electrical insulating properties, etc.

Although the polycarboxylic compound is not limited to a particular one, a particularly preferred embodiment is the case that R is a cyclohexene ring. When this compound is copolymerized with the hydrogenated bisphenolic epoxy compound as the other monomer component, the resultant resin is a linear epoxy resin of the alternating copolymerization type containing regularly repeating cyclohexene rings, which excels in photocuring properties because it has no aromatic ring and gives a cured product having the well-balanced toughness and flexibility at a higher level.

As the hydrogenated bisphenolic epoxy compound (a mentioned above, for example, “EPIKOTE YL-6663”, product name of Japan Epoxy Resin K.K., and “Epo Tohto ST-2004”, “Epo Tohto ST-2007”, and “Epo Tohto ST-3000”, product names of Tohto Kasei Co., Ltd., etc. may be cited. These epoxy compounds may be used either singly or in the form of a combination of two or more members.

As the polycarboxylic compound (b), dicarboxylic acids such as cyclohexene-1,4-dicarboxylic acid, tetrahydrophthalic acid, hexahydrophthalic acid, hexahydroisophthalic acid, hexahydroterephthalic acid, phthalic acid, isophthalic acid, terephthalic acid, succinic acid, adipic acid, muconic acid, and suberic acid can be advantageously used. These polycarboxylic compounds, preferably dicarboxylic acids, may be used either singly or in the form of a-combination of two or more members.

As the catalyst to be used for the reaction of the hydrogenated bisphenolic epoxy compound (a) with the polycarboxylic compound (b), it is desirable to use such catalysts as phosphines, alkali metal compounds, and amines, by which the epoxy group reacts with the carboxyl group quantitatively, either singly or in the form of a combination of two or more members. The use of other catalysts is not desirable because a monomer component reacts with an alcoholic hydroxyl group caused by the reaction of the epoxy group with the carboxyl group to give rise gelation.

As the phosphines, trialkyl or triaryl phosphines such as tributylphosphine and triphenylphosphine, salts thereof with an oxide, etc. may be cited. They may be used either singly or in the form of a combination of two or more members.

As the alkali metal compounds, hydroxides, halides, alcoholates, amides, etc. of alkali metals such as sodium, lithium, and potassium may be cited. These compounds may be used either singly or in the form of a combination of two or more members.

As the amines, aliphatic or aromatic primary, secondary, tertiary, and quaternary amines may be cited. These amines may be used either singly or in the form of a combination of two or more members. As concrete examples of the amines, triethanolamine, N,N-dimethylpiperazine, triethylamine, tri-n-propylamine, hexamethylenetetramine, pyridine, tetrametylammonium bromide, etc. may be cited.

The amount of the catalyst to be used is preferred to be in the range of 0.1 to 25 mol %, more preferably 0.5 to 20 mol %, most preferably 1 to 15 mol %, based on one mol of the epoxy group of the hydrogenated bisphenolic epoxy compound (a). This is because if the amount of the catalyst to be used is less than 0.1 mol % of the epoxy group, the reaction will take much time uneconomically. Conversely, a large amount exceeding 25 mol % is not desirable from the reason that the reaction speed becomes rapid uncontrollably.

The polyaddition reaction of the hydrogenated bisphenolic epoxy compound (a) with the polycarboxylic compound (b) is preferred to be carried out in an stream of an inert gas or in the air in the presence of a catalyst mentioned above at a temperature in the approximate range of 50 to 200° C., more preferably in the approximate range of 80 to 150° C. If the reaction temperature is lower than 50° C., the reaction will not proceed to a satisfactory extent. Conversely, the reaction temperature exceeding 200° C. is not desirable from the reason that the by-reaction of hydroxyl groups of the resultant product with epoxy groups will proceed and the product will tend to cause gelation. Although the reaction time may be suitably selected depending on the reactivity of the raw materials to be used and the reaction temperature, the preferred reaction time is about 5 to 72 hours.

Next, the synthesis of the polynuclear epoxy resin (A″) will be described.

The polynuclear epoxy resin (A″) may be produced by reacting an epihalohydrin (c) with alcoholic secondary hydroxyl groups of the linear epoxy resin (A′) obtained as described above and represented by the general formula (1) in a known solvent to be described hereinafter in the presence of an alkali metal hydroxide such as caustic soda. The resultant polynuclear epoxy resin (A″) has the structure as represented by the following general formula (2), for example, in case epichlorohydrin is used as the epihalohydrin.

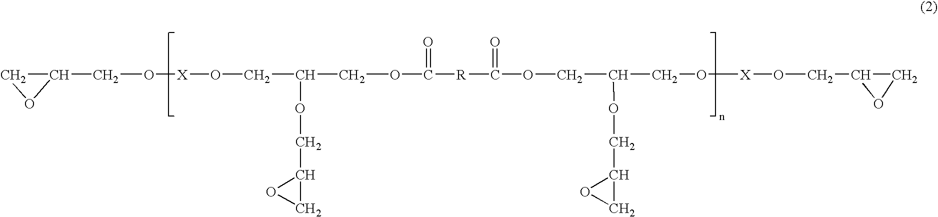

Wherein R, X, and n have the same meanings as those mentioned above.

As the epihalohydrin (c) mentioned above, for example, epichlorohydrin, epibromohydrin, epiiodohydrin, β-methyl epichlorohydrin, β-methyl epibromohydrin, β-methyl epiiodohydrin, etc. may be used.

In the linear polynuclear epoxy resin (A″) as represented by the general formula (2) mentioned above, the amount of the epihalohydrin (c) to be used will be sufficient in 0.1 equivalent or more, based on one equivalent the alcoholic secondary hydroxyl group of the linear epoxy resin (A′) mentioned above. However, the use of the amount exceeding 15 equivalents per one equivalent of hydroxyl group is not desirable from the reason that the volumetric efficiency becomes poor.

As the solvent, known solvents such as non-protonic polar solvents like dimethyl sulfoxide, N,N-dimethylformamide, and N,N-dimethylacetamide and aromatic hydrocarbons like toluene and xylene may be cited. The amount of the solvent to be used is preferred to be in the range of 5 to 300% by weight based on the linear epoxy resin (A′) mentioned above. This is because if the amount of the solvent to be used is less than 5% by weight, the reaction of the epihalohydrin with the alcoholic hydroxyl group will become unduly slow. Conversely, the use of the amount exceeding 300% by weight is not desirable from the reason that the volumetric efficiency becomes poor.

As the alkali metal hydroxides, caustic soda, caustic potash, lithium hydroxide, calcium hydroxide, etc. may be used. Among other compounds, caustic soda proves to be particularly desirable. The amount of the alkali metal hydroxide to be used is preferred to be in the range of 0.5 to 2 mols, based on one mol of the alcoholic hydroxyl group destined to be epoxidized of the linear epoxy resin (A′) mentioned above.

The temperature of the reaction of the epihalohydrin (c) with the alcoholic hydroxyl group of the linear epoxy resin (A′) mentioned above is preferred to be in the range of 20 to 100° C. This is because if the reaction temperature is lower than 20° C., the reaction will become unduly slow and need much time for completion. Conversely, the reaction temperature exceeding 100° C. is not desirable from the reason that the by-reaction will proceed.

The reaction of the epihalohydrin (c) with the alcoholic hydroxyl group of the linear epoxy resin (A′) mentioned above may be carried out by adjusting the amount of the alkali metal hydroxide mentioned above under the conditions of the coexistence of the alkali metal hydroxide and dimethyl sulfoxide or a quaternary ammonium salt or 1,3-dimethyl-2-imidazoline. In this reaction, a solvent such as alcohols like methanol and ethanol, aromatic hydrocarbons like toluene and xylene, ketones like methyl isobutyl ketone and methyl ethyl ketone, and cyclic ether compounds like tetrahydrofuran may be used together with the above compounds.

As concrete examples of the quaternary ammonium salt, tetramethyl ammonium chloride, tetramethyl ammonium bromide, trimethyl ammonium chloride, etc. may be cited. The amount of this salt to be used is preferred to be in the range of 0.3 to 45 mol %, based on one mol of the hydroxyl group destined to be epoxidized of the linear epoxy resin (A′) used as a raw material. This is because if the amount of the quaternary ammonium salt to be used is less than 0.3 mol % based on one mol of the hydroxyl group destined to be epoxidized, the reaction of the epihalohydrin with the alcoholic hydroxyl group of the linear epoxy resin (A′) used as a raw material will become unduly slow and need much time for completion. Conversely, the use of the amount exceeding 45 mol % based on one mol of the hydroxyl group destined to be epoxidized is not desirable from the reason that a remarkable effect will not be obtained even when the quaternary ammonium salt is present in such a large amount with the result of increase in cost.

Then, the synthesis of the epoxy ester of an unsaturated monocarboxylic acid will be described.

The epoxy ester of an unsaturated monocarboxylic acid of the present invention can be produced by causing the reaction of an unsaturated monocarboxylic acid (d) with the linear polynuclear epoxy resin (A″) mentioned above in the presence of an organic solvent to be described hereinafter or in the absence of a solvent and also in the presence of a polymerization inhibitor such as hydroquinone and oxygen in combination with a reaction catalyst such as a tertiary amine like triethylamine, a quaternary ammonium salt like triethylbenzyl ammonium chloride, an imidazole compound like 2-ethyl-4-methylimidazole, and a phosphorus compound like triphenyl phosphine, usually at a temperature in the approximate range of 80 to 130° C.

When acrylic acid, for example, as the unsaturated monocarboxylic acid (d) is caused to react with the linear polynuclear epoxy resin (A″) as represented by the general formula (2) mentioned above, an epoxy ester of an unsaturated monocarboxylic acid represented by the following general formula (3) may be obtained.

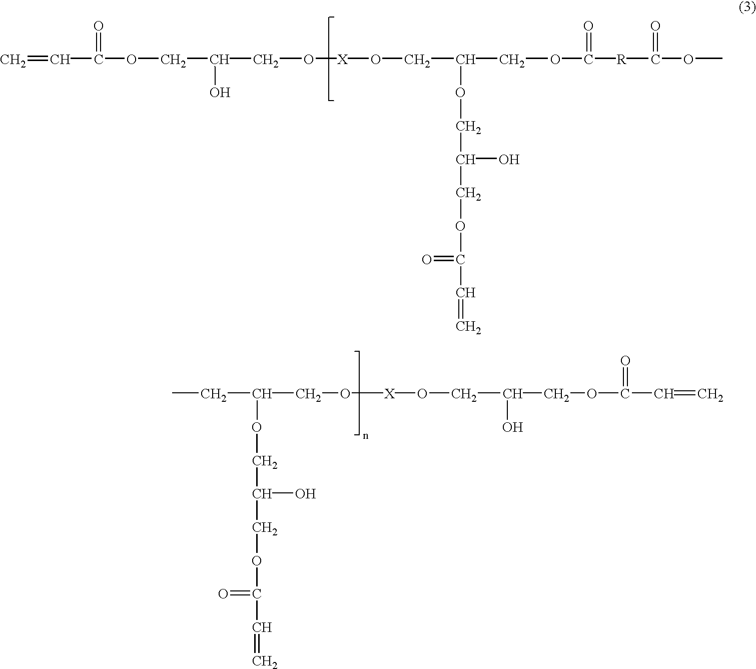

Wherein R, X, and n have the same meanings as those mentioned above. Incidentally, although the general formula (3) mentioned above shows the structure that acrylic acid is added to all the epoxy groups in both terminals and side chains of the polynuclear epoxy resin (A″) represented by the general formula (2) mentioned above, the products having the structures that acrylic acid is added to part of the epoxy groups (in both terminals and side chains) or a mixture of the products having these structures may be obtained depending on the addition ratio of the acrylic acid. This can be adjusted by the degree of reaction of the acrylic acid (the unsaturated monocarboxylic acid).

The production of the epoxy ester of an unsaturated monocarboxylic acid by reacting an unsaturated monocarboxylic acid (d) with the linear polynuclear epoxy resin (A″) mentioned above can be performed by compounding an unsaturated monocarboxylic acid (d) with the linear polynuclear epoxy resin (A″) mentioned above in a proportion of 0.2 to 1.3 mols, based on one mol of the epoxy group contained in the resin, and heating the mixture to a temperature in the approximate range of 60 to 150° C., preferably in the range of 70 to 130° C., in the presence of a solvent or in the absence of a solvent, preferably in the presence of air, to effect the reaction. In order to prevent the gelation caused by the polymerization during the reaction, it is preferred to use a well-known and widely used polymerization inhibitor such as hydroquinones like methylhydroquinone and hydroquinone, and benzoquinones like p-benzoquinone and p-toluquinone. Further, for the purpose of shortening the reaction time, it is preferred to use an esterification catalyst.

As the esterification catalyst, any well-known and widely used compounds such as tertiary amines like N,N-dimethylaniline, pyridine, and triethylamine and their hydrochloride or hydrobromide; quaternary ammonium salts like tetramethyl ammonium chloride and triethylbenzyl ammonium chloride; sulfonic acids like p-toluenesulfonic acid; sulfonium salts like dimethyl sulfoxide and methyl sulfoxide; phosphines like triphenyl phosphine and tri-n-butyl phosphine; and metal halides like lithium chloride, lithium bromide, stannous chloride, and zinc chloride may be used.

As an inert solvent, for example, toluene, xylene, etc. may be used.

As typical examples of the unsaturated monocarboxylic acids (d), acrylic acid, methacrylic acid, cinnamic acid, crotonic acid, sorbic acid, α-cyanocinnamic acid, β-styrylacrylic acid, and an unsaturated dibasic acid anhydride adduct of a hydroxyl group-containing acrylate such as hydroxyethyl (meth) acrylate, hydroxypropyl (meth) acrylate, hydroxybutyl (meth)acrylate, trimethylol propane di(meth)acrylate, pentaerythritol tri(meth)acryalte, dipentaerythritol penta(meth)acrylate, phenyl glycidyl (meth)acrylate, and caprolactone adduct of (meth)acrylic acid may be cited. Among other unsaturated monocarboxylic acids (d) cited above, acrylic acid and methacrylic acid prove to be particularly desirable. These unsaturated monocarboxylic acids may be used either singly or in the form of a combination of two or more members. Incidentally, the term “(meth)acrylate” as used in this specification refers collectively to acrylate and methacrylate. This holds good for other similar expression.

Next, the synthesis of the actinic energy ray-curable resin of the present invention will be described.

The actinic energy ray-curable resin (A) of the present invention is obtained by reacting a polybasic acid anhydride (e) with an alcoholic hydroxyl group of the epoxy ester of an unsaturated monocarboxylic acid produced by the reaction mentioned above. In this reaction, the amount of the polybasic acid anhydride (e) to be used is preferred to be in such an addition ratio that the acid value of the produced actinic energy ray-curable resin falls in the range of 50 to 200 mg KOH/g, preferably 50 to 120 mg KOH/g. If the acid value of the actinic energy ray-curable resin is less than 50 mg KOH/g, the resultant product will manifest insufficient solubility in an aqueous alkaline solution and the coating film formed therefrom will be developed only with difficulty. Conversely, the acid value exceeding 200 mg KOH/g is not preferred from the reason that the coating film will be developed even in the surface of the exposed part without reference to the conditions of the exposure.

When the polybasic acid anhydride (e) is caused to react with the epoxy ester of an unsaturated monocarboxylic acid as represented by the general formula (3) mentioned above, for example, the actinic energy ray-curable resin as represented by the following general formula (4) may be obtained.

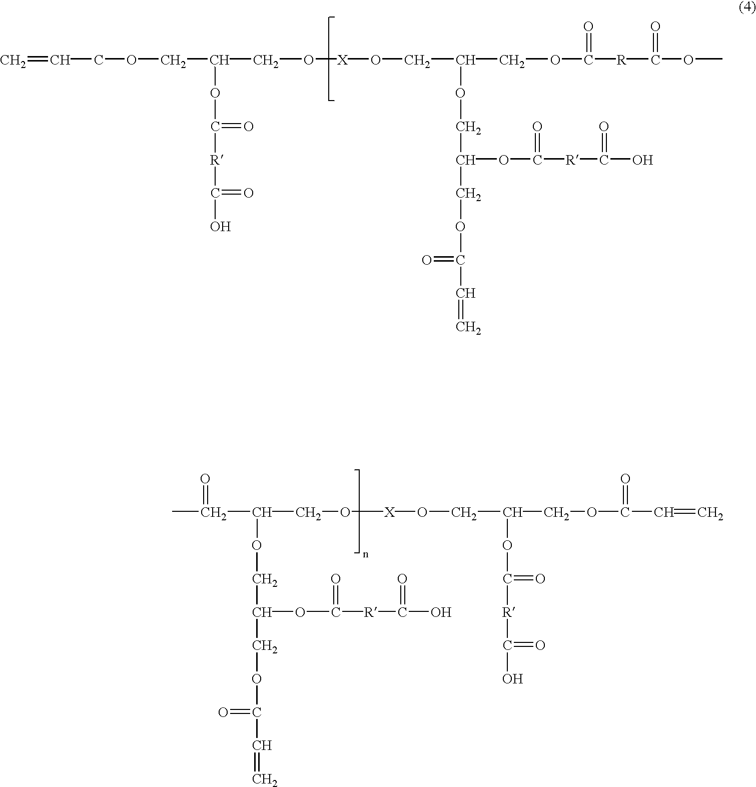

Wherein R, X, and n have the same meanings as those mentioned above and R′ represents a polybasic acid anhydride residue. Incidentally, although the general formula (4) mentioned above shows the structure that the polybasic acid anhydride is added to all the secondary hydroxyl groups of the epoxy ester of an unsaturated monocarboxylic acid represented by the general formula (3) mentioned above, the products having the structures that the polybasic acid anhydride is added to part of the secondary hydroxyl groups or a mixture of the products having these structures may be obtained depending on the addition ratio of the polybasic acid anhydride. This can be adjusted by the degree of reaction of the polybasic acid anhydride.

The above-mentioned reaction is carried out usually at a temperature in the approximate range of 50 to 130° C. in the presence of an organic solvent to be described hereinafter or in the absence of a solvent and also in the presence of a polymerization inhibitor such as hydroquinone and oxygen. In this reaction, as occasion demands, a tertiary amine such as triethylamine, a quaternary ammonium salt such as triethylbenzyl ammonium chloride, an imidazole compound such as 2-ethyl-4-methylimidazole, and a phosphorus compound such as triphenyl phosphine may be added as a catalyst.

As the polybasic acid anhydrides (e) mentioned above, alicyclic dibasic acid anhydrides such as methyltetrahydrophthalic anhydride, tetrahydrophthalic anhydride, hexahydrophthalic anhydride, methylhexahydrophthalic anhydride, nadic anhydride, 3,6-endomethylenetetrahydrophthalic anhydride, methylendomethylenetetrahydrophthalic anhydride, and tetrabromophthalic anhydride; aliphatic or aromatic dibasic acid anhydrides such as succinic anhydride, maleic anhydride, itaconic anhydride, octenylsuccinic anhydride, pentadodecenylsuccinic anhydride, phthalic anhydride, and trimellitic anhydride; and aliphatic or aromatic tetrabasic acid dianhydrides such as biphenyl-tertacarboxylic dianhydride, diphenyl ether-tertacarboxylic dianhydride, butane-tertacarboxylic dianhydride, cyclopentane-tertacarboxylic dianhydride, pyromellitic anhydride, and benzophenone-tetracarboxylic dianhydride may be cited. These polybasic acid anhydrides may be used either singly or in the form of a combination of two or more members. Among other polybasic acid anhydrides cited above, alicyclic dibasic acid anhydrides prove to be particularly desirable.

The actinic energy ray-curable resin (A) of the present invention has a number-average molecular weight in the range of 900 to 100,000, preferably 900 to 20,000, more preferably 900 to 10,000. If the number-average molecular weight of the actinic energy ray-curable resin is lower than 900, a cured product obtained therefrom will exhibit insufficient toughness. Conversely, if the number-average molecular weight exceeds 100,000, the cured product will be at a disadvantage in exhibiting poor developing properties.

As the photopolymerization initiators (B) mentioned above, for example, benzoin and alkyl ethers thereof such as benzoin, benzoin methyl ether, benzoin ethyl ether, and benzoin isopropyl ether; acetophenones such as acetophenone, 2,2-dimethoxy-2-phenyl acetophenone, 2,2-diethoxy-2-phenyl acetophenone, and 1,1-dichloroacetophenone; aminoacetophenones such as 2-methyl-1-[4-(methylthio)phenyl]-2-morpholinopropanone-1,2-benzyl-2-dimethylamino-1-(4-morpholinophenyl)-butan-1-one, and N,N-dimethylamino-acetophenone; anthraquinones such as 2-methylanthraquinone, 2-ethylanthraquinone, 2-t-butylanthraquinone, and 1-chloroanthraquinone; thioxanthones such as 2,4-dimethylthioxanthone, 2,4-diethylthioxanthone, 2-chlorothioxanthone, and 2,4-diisbpropylthioxanthone; ketals such as acetophenone dimethyl ketal and benzyl dimethyl ketal; organic peroxides such as benzoyl peroxide and cumene peroxide; dimer of 2,4,5-triaryl imidazole, riboflavin tetrabutylate, thiol compounds such as 2-mercaptobenzimidazole, 2-mercaptobenzoxazole, and 2-mercaptobenzothiazole; 2,4,6-tris-S-triazine; organic halogen compounds such as 2,2,2-tribromoethanol and tribromomethyl phenyl sulfone; benzophenones such as benzophenone and 4,4′-bis(diethylamino)benzophenone or xanthones; 2,4,6-trimethylbenzoyl diphenyl phosphine oxide etc. may be cited. These well known and widely used photopolymerization initiators may be used either singly or in the form of a mixture of two or more members, or further in combination with a photo-initiator aid such as tertiary amines like N,N-(dimethylamino)ethylbenzoate, N,N-(dimethylamino)isoamylbenzoate, penthyl-4-dimethylaminobenzoate, triethyl amine, and triethanol amine. Further, a titanothene compound such as CGI-784 (product of Ciba Specialty Chemicals Inc.) and the like which exhibit absorption in a visible region may be added to promote the photochemical reaction. Particularly preferred photopolymerization initiator is 2-methyl-1-[4-(methylthio)phenyl]-2-morpholinopropanone-1,2-benzyl-2-dimethylamino-1-(4-morpholinophenyl)-butan-1-one, etc., but not limited to these compounds. Any compounds which absorb light in the ultraviolet region or visible region and cause radical polymerization of the unsaturated groups such as (meth)acryloyl groups may be used either singly or in the form of a combination of two or more members irrespective of the photopolymerization initiator or the photo-initiator aid.

The amount of the photopolymerization initiator (in case the photo-initiator aid is used, the total amount thereof) to be used is preferred to be in the range of 0.1 to 25 parts by weight, preferably 0.5 to 20 parts by weight, based on 100 parts by weight of the aforementioned actinic energy ray-curable resin (A) (as a solid content, this holds good for the same expression to be described hereinafter). If the amount of the photopolymerization initiator to be used is less than the lower limit of the range mentioned above, the composition will not be cured by irradiation of actinic energy rays or the irradiation time should be prolonged, and a coating film of satisfactory properties will be obtained only with difficulty. Conversely, even if the photopolymerization initiator is added to the composition in a large amount exceeding the upper limit of the range mentioned above, the composition will not attain the further improvement in the photocuring properties and such a large amount is not desirable from the economical viewpoint.

As the diluent (C) mentioned above, a photopolymerizable vinyl monomer and/or an organic solvent may be used.

As the typical examples of the photopolymerizable vinyl monomers, hydroxyalkyl acrylates such as 2-hydroxyethyl acrylate and 2-hydroxypropyl acrylate; mono- or di-acrylates of glycols such as ethylene glycol, methoxytetraethylene glycol, polyethylene glycol, and propylene glycol; acrylamides such as N,N-dimethyl acrylamide, N-methylol acrylamide, and N,N-dimethylaminopropyl acrylamide; aminoalkyl acrylates such as N,N-dimethylaminoethyl acrylate and N,N-dimethylaminopropyl acrylate; polyfunctional acrylates of polyhydric alcohols such as hexane diol, trimethylol propane, pentaerythritol, dipentaerythritol, and tris-hydroxyethyl isocyanurate, and ethylene oxide adducts or propylene oxide adducts of these polyhydric alcohols; phenoxyethyl acrylate, bisphenol A diacrylate and acrylates of ethylene oxide adducts or propylene oxide adducts of these phenols; acrylates of glycidyl ethers such as glycerin diglycidyl ether, glycerin triglycidyl ether, trimethylol propane triglycidyl ether, and triglycidyl isocyanurate; and melamine acrylate, and methacrylates corresponding to the acrylates mentioned above may be cited.

As the organic solvents, ketones such as methyl ethyl ketone and cyclohexanone; aromatic hydrocarbons such as toluene, xylene, and tetramethyl benzene; glycol ethers such as cellosolve, methyl cellosolve, butyl cellosolve, carbitol, methyl carbitol, butyl carbitol, propylene glycol monomethyl ether, dipropylene glycol monomethyl ether, dipropylene glycol diethyl ether, and triethylene glycol monoethyl ether; esters such as ethyl acetate, butyl acetate, and acetates of glycol ethers mentioned above; alcohols such as ethanol, propanol, ethylene glycol, and propylene glycol; aliphatic hydrocarbons such as octane and decane; and petroleum solvents such as petroleum ether, petroleum naphtha, hydrogenated petroleum naphtha, and solvent naphtha may be cited. Among other solvents cited above, those which exhibit good compatibility with the actinic energy ray-curable resin (A) mentioned above and do not dissove a thermosetting component (D) therein prove to be particularly desirable.

The diluents mentioned above may be used either singly or in the form of a mixture of two or more members. The amount of the diluent to be used, when the photopolymerizable vinyl monomer is used, is desired to fall in the range of 10 to 60 parts by weight, preferably 15 to 50 parts by weight, based on 100 parts by weight of the actinic energy ray-curable resin (A). The amount of the photopolymerizable vinyl monomer larger than the upper limit of the range mentioned above is not desirable because a tack-free touch of finger of a coating film will be impaired. Though the amount of the organic solvent to be used is not particularly restricted, it is properly in the approximate range of 30 to 300 parts by weight, based on 100 parts by weight of the actinic energy ray-curable resin (A) mentioned above. The amount of the organic solvent may be suitably set so as to fit the method of application to be selected.

With respect to the purpose of use of the diluent (C), the photopolymerizable vinyl monomer is used for the purpose of diluting the photosenstive components thereby rendering the produced composition easily applicable, and improving the photopolymerizability of the composition. On the other hand, the organic solvent is used for the purpose of dissolving the photosensitive components, diluting the composition, allowing the composition to be applied in the from of a liquid, enabling the applied layer of the composition to form a film by drying, and allowing the film to be exposed to light by the contact exposure. Accordingly, either exposure method of the contact exposure method in which a photomask is closely superposed on a coating film or the non-contact exposure method is used depending on the diluent to be used.

Concrete examples of the aforementioned polyfunctional epoxy compound (D) include bisphenol A type epoxy resins represented by EPIKOTE 828, EPIKOTE 834, EPIKOTE 1001, and EPIKOTE 1004 produced by Japan Epoxy Resin K.K., EPICLON 840, EPICLON 850, EPICLON 1050, and EPICLON 2055 produced by Dainippon Ink and Chemicals Inc., Epo Tohto YD-011, YD-013, YD-127, and YD-128 produced by Tohto Kasei Co., Ltd., D.E.R. 317, D.E.R. 331, D.E.R. 661, and D.E.R. 664 produced by The Dow Chemical Company, ARALDITE 6071, ARALDITE 6084, ARALDITE GY250, and ARALDITE GY260 produced by Ciba Specialty Chemicals Inc., Sumi-epoxy ESA-011, ESA-014, ELA-115, and ELA-128 produced by Sumitomo Chemical Co., Ltd., and A.E.R. 330, A.E.R. 331, A.E.R. 661, and A.E.R. 664 produced by Asahi Chemical Industry Co., Ltd. (all trade names); brominated epoxy resins represented by EPIKOTE YL903 produced by Japan Epoxy Resin K.K., EPICLON 152 and EPICLON 165 produced by Dainippon Ink and Chemicals Inc., Epo Tohto YDB-400 and YDB-500 produced by Tohto Kasei Co., Ltd., D.E.R. 542 produced by The Dow Chemical Company, ARALDITE 8011 produced by Ciba Specialty Chemicals Inc., Sumi-epoxy ESB-400 and ESB-700 produced by Sumitomo Chemical Co., Ltd., and A.E.R. 711 and A.E.R. 714 produced by Asahi Chemical Industry Co., Ltd. (all trade names); novolak type epoxy resins represented by EPIKOTE 152 and EPIKOTE 154 produced by Japan Epoxy Resin K.K., D.E.N. 431 and D.E.N. 438 produced by The Dow Chemical Company, EPICLON N-730, EPICLON N-770, and EPICLON N-865 produced by Dainippon Ink and Chemicals Inc., Epo Tohto YDCN-701 and YDCN-704 produced by Tohto Kasei Co., Ltd., ARALDITE ECN1235, ARALDITE ECN1273, ARALDITE ECN1299, and ARALDITE XPY307 produced by Ciba Specialty Chemicals Inc., EPPN-201, EOCN-1025, EOCN-1020, EOCN-104S, and RE-306 produced by Nippon Kayaku Co., Ltd., Sumi-epoxy ESCN-195× and ESCN-220 produced by Sumitomo Chemical Co., Ltd., and A.E.R. ECN-235 and ECN-299 produced by Asahi Chemical Industry Co., Ltd. (all trade names); bisphenol F type epoxy resins represented by EPICLON 830 produced by Dainippon Ink and Chemicals Inc., EPIKOTE 807 produced by Japan Epoxy Resin K.K., Epo Tohto YDF-170, YDF-175, and YDF-2004 produced by Tohto Kasei Co., Ltd., and ARALDITE XPY306 produced by Ciba Specialty Chemicals Inc. (all trade names); hydrogenated bisphenol A type epoxy resins represented by Epo Tohto ST-2004, ST-2007, and ST-3000 produced by Tohto Kasei Co., Ltd. (all trade names); glycidylamine type epoxy resins represented by EPIKOTE 604 produced by Japan Epoxy Resin K.K., Epo Tohto YH-434 produced by Tohto Kasei Co., Ltd., ARALDITE MY720 produced by Ciba Specialty Chemicals Inc., and Sumi-epoxy ELM-120 produced by Sumitomo Chemical Co., Ltd. (all trade names); hydantoin type epoxy resins such as ARALDITE CY-350 produced by Ciba Specialty Chemicals Inc. (trade name); alicyclic epoxy resins represented by Celloxide 2021 produced by Daicel Chemical Industries, Ltd., and ARALDITE CY175 and CY179 produced by Ciba Specialty Chemicals Inc. (all trade names); trihydroxyphenyl methane type epoxy resins represented by YL-933 produced by Japan Epoxy Resin K.K., T.E.N. produced by The Dow Chemical Company, and EPPN-501 and EPPN-502 produced by Nippon Kayaku Co., Ltd. (all trade names); bixylenol type or biphenol type epoxy resins or mixtures thereof represented by YL-6056, YX-4000, and YL-6121 produced by Japan Epoxy Resin K.K. (all trade names); bisphenol S type epoxy resins represented by EBPS-200 produced by Nippon Kayaku Co., Ltd., EPX-30 produced by Asahi Denka Kogyo K.K., and EXA-1514 produced by Dainippon Ink and Chemicals Inc. (all trade names); bisphenol A novolak type epoxy resins represented by EPIKOTE 157S (trade name) produced by Japan Epoxy Resin K.K.; tetraphenylol ethane type epoxy resins represented by EPIKOTE YL-931 produced by Japan Epoxy Resin K.K., and ARALDITE 163 produced by Ciba Specialty Chemicals Inc. (all trade names); heterocyclic epoxy resins represented by ARALDITE PT810 produced by Ciba Specialty Chemicals Inc. and TEPIC produced by Nissan Chemical Industries Ltd. (all trade names); diglycidyl phthalate resin represented by BLEMMER DGT (trade name) produced by Nippon Oil and Fats Co., Ltd.; tetraglycidyl xylenoyl ethane resins represented by ZX-1063 (trade name) produced by Tohto Kasei Co., Ltd.; naphthalene group-containing epoxy resins represented by ESN-190 and ESN-360 produced by Shinnittetsu Chemical Co., Ltd. and HP-4032, EXA-4750, and EXA-4700 produced by Dainippon Ink and Chemicals Inc. (all trade names); dicyclopentadiene skeleton-containing epoxy resins represented by HP-7200 and HP-7200H produced by Dainippon Ink and Chemicals Inc. (all trade names); glycidylmethacrylate copolymer type epoxy resins represented by CP-50S and CP-50M produced by Nippon Oil and Fats Co., Ltd. (all trade names); and copolymeric epoxy resin of cyclohexylmaleimide and glycidyl methacrylate, but are not limited to these epoxy resins. These epoxy resins may be used either singly or in the form of a combination of two or more members. Among other epoxy resins cited above, biphenol type or bixylenol type epoxy resins or mixtures thereof prove to be particularly desirable.

The polyfunctional epoxy compounds (D) mentioned above contribute to the improvement in such properties as adhesiveness and heat resistance of the solder resist through their thermal cure. The sufficient amount of the epoxy compound to be incorporated in the composition is in the range of not less than 10 parts by weight and not more than 100 parts by weight, preferably 25 to 60 parts by weight, based on 100 parts by weight of the aforementioned actinic energy ray-curable resin (A). If the amount of the polyfunctional epoxy compound (D) to be incorporated is less than 10 parts by weight, the hygroscopicity of the cured film will tend to become so high that the PCT resistance will be degraded and the resistance to soldering heat and resistance to electroless plating will be degraded. Conversely, if the amount exceeds 100 parts by weight, the developing properties of the coating film and the resistance to electroless plating of the cured film will be degraded and the PCT resistance will also be degraded.

As the epoxy curing catalysts (E) mentioned above, for example, imidazole and imidazole derivatives such as 2-methylimidazole, 2-ethylimidazole, 2-ethyl-4-methylimidazole, 2-phenylimidazole, 4-phenylimidazole, 1-cyanoethyl-2-phenylimidazole, and 1-(2-cyanoethyl)-2-ethyl-4-methylimidazole; amine compounds such as dicyandiamide, benzyldimethyl amine, 4-(dimethylamino)-N,N-dimethylbenzyl amine, 4-methoxy-N,N-dimethylbenzyl amine, 4-methyl-N,N-dimethylbenzyl amine; hydrazine compounds such as hydrazide adipate and hydrazide sebacate; and phosphorus compound such as triphenylphosphine may be used. The curing catalysts which are commercially available include products of Shikoku Chemicals Co., Ltd., 2MZ-A, 2MZ-OK, 2PHZ, 2P4BHZ, and 2P4 MHZ (invariably trade names for imidazole type compounds) and products of Sun-Apro K.K., U-CAT3503X and U-CAT3502X (invariably trade names for isocyanate compounds blocked with dimethyl amine) and DBU, DBN, U-CATSA102, and U-CAT5002 (invariably trade names for dicyclic amizine compounds and salts thereof), for example. The curing catalysts are not limited to the compounds cited above and any curing catalysts for epoxy resin and any compounds which can promote the reaction of epoxy groups with carboxyl groups may be used. The curing catalysts may be used either singly or in the form of a mixture of two or more members. Furthermore, S-triazine derivatives which also act as an adhesiveness-imparting agent, such as guanamine, acetoguanamine, benzoguanamine, melamine, 2,4-diamino-6-methacryloyloxyethyl-S-triazine, 2-vinyl-4,6-diamino-S-triazine, isocyanuric acid adduct of 2-vinyl-4,6-diamino-S-triazine, isocyanuric acid adduct of 2,4-diamino-6-methacryloyloxyethyl-S-triazine can also be used. Preferably, the compound which also acts as an adhesiveness-imparting agent is used in combination with the epoxy curing catalysts mentioned above. The amount of the epoxy curing catalyst (E) mentioned above to be incorporated in the composition may be in the conventionally used range, for example, in the range of 0.1 to 20 parts by weight, preferably 0.5 to 15.0 parts by weight, based on 100 parts by weight of the actinic energy ray-curable resin (A) mentioned above.

Further, the photocurable and thermosetting resin composition of the present invention may contain an actinic energy ray-curable resin (G) other than the actinic energy ray-curable resin (A) mentioned above in amounts not so large as to impair the effects of the present invention.

As the other actinic energy ray-curable resin (G), any resin may be used insofar as it has an unsaturated group and a carboxyl group and not limited to a particular one. However, the resins as listed below can be particularly advantageously used:

(1) carboxyl group-containing photosensitive resins obtained by adding ethylenically unsaturated groups as pendants to a copolymer of an unsaturated carboxylic acid and an unsaturated double bond-containing compound,

(2) carboxyl group-containing photosensitive resins obtained by reacting an unsaturated carboxylic acid with a copolymer of a compound having an epoxy group and an unsaturated double bond and an unsaturated double bond-containing compound and further reacting a polybasic acid anhydride with the resultant secondary hydroxyl group,

(3) carboxyl group-containing photosensitive resins obtained by reacting a compound having a hydroxyl group and an unsaturated double bond with a copolymer of an unsaturated double bond-containing acid anhydride and an unsaturated double bond-containing compound,

(4) carboxyl group-containing photosensitive resins obtained by reacting an epoxy compound with an unsaturated monocarboxylic acid and further reacting a polybasic acid anhydride with the resultant secondary hydroxyl group,

(5) carboxyl group-containing photosensitive resins obtained by further reacting a compound having an epoxy group and an unsaturated double bond with a carboxyl group-containing resin obtained by the reaction of a polybasic acid anhydride with a hydroxyl group-containing polymer,

(6) carboxyl group-containing photosensitive resins obtained by reacting an unsaturated monocarboxylic acid with a polyfunctional oxetane compound and further reacting a polybasic acid anhydride with a primary hydroxyl group of the resultant modified oxetane resin, and

(7) carboxyl group-containing photosensitive resins obtained by reacting an unsaturated monocarboxylic acid with a polynuclear epoxy compound and further reacting a polybasic acid anhydride with a primary hydroxyl group of the reaction product.

Among other carboxyl group-containing photosensitive resins cited above, the incorporation of the actinic energy ray-curable resin obtained by using a cresol novolak type epoxy compound proves to be particularly desirable for the purpose of improving the heat resistance of a cured product obtained.

The photocurable and thermosetting resin composition of the present invention may further contain a spherical porous filler (F), for the purpose of decreasing the dielectric constant and the dielectric dissipation factor of a cured product thereof without inducing the reduction in various properties such as the coating properties and heat resistance. As a material for the spherical porous filler, silica and cross-linked resinous substances may be cited.

When a usual filler is incorporated in the photocurable and thermosetting resin composition, the dielectric constant and the dielectric dissipation factor of a cured product is governed by the dielectric constant and the dielectric dissipation factor of the filler. However, when a spherical porous filler is incorporated in the composition, the dielectric characteristics thereof can be lowered because the filler retains air in its pores. In order to retain the air therein, the spherical porous filler is preferred to have an average particle diameter in the range of 1 to 15 μm, more preferably in the range of 1 to 100 μm. Further, the spherical porous filler is preferred to have the oil absorption in the approximate range of 50 to 800 m²/g, preferably 100 to 200 m²/g.

The amount of the spherical porous filler (F) to be incorporated in the composition is preferred to be in the range of not less than 5 parts by weight and not more than 100 parts by weight, based on 100 parts by weight of the actinic energy ray-curable resin (A) mentioned above.

The photocurable and thermosetting resin composition of the present invention may contain an epoxidized polybutadiene (H) for the purpose of imparting the flexibility and toughness thereto. This epoxidized polybutadiene (H) includes, for example, EPOLEAD PB3600, PB4700, etc. manufactured by Daicel Chemical Industries, Ltd. The amount of the epoxidized polybutadiene to be incorporated in the composition is preferred to be in the range of 5 to 50 parts by weight, based on 100 parts by weight of the actinic energy ray-curable resin (A) mentioned above.

Furthermore, the composition may contain spherical urethane beads (I) of an average particle diameter in the range of 1 to 15 μm for the purpose of imparting the flexibility and the low warpage thereto. The amount of spherical urethane beads (I) to be incorporated in the composition is preferred to be in the range of 5 to 100 parts by weight, based on 100 parts by weight of the actinic energy ray-curable resin (A) mentioned above.

The photocurable and thermosetting resin composition of the present invention may further incorporate therein, as occasion demands, a well known and widely used inorganic filler such as barium sulfate, barium titanate, silicon oxide powder, finely pulverized silicon oxide, amorphous silica, crystalline silica, fused silica, spherical silica, talc, clay, magnesium carbonate, calcium carbonate, aluminum oxide, aluminum hydroxide, and mica singly or in the combination of two or more members. These fillers are used for the purpose of suppressing the shrinkage of a coating film on curing and enhancing the characteristics of the coating film such as adhesiveness and hardness. The suitable amount of the inorganic filler to be incorporated in the composition is in the range of 10 to 300 parts by weight, preferably 30 to 200 parts by weight, based on 100 parts by weight of the actinic energy ray-curable resin (A) mentioned above.

The composition of the present invention may further incorporate therein, as occasion demands, any of known and commonly used coloring agents such as phthalocyanine blue, phthalocyanine green, iodine green, disazo yellow, crystal violet, titanium oxide, carbon black, and naphthalene black, any of known and commonly used thermal polymerization inhibitors such as hydroquinone, hydroquinone monomethyl ether, tert-butyl catechol, pyrogallol, and phenothiazine, any of known and commonly used thickening agents such as finely powdered silica, organobentonite, and montmorillonite, silicone type, fluorine type, or macromolecular type anti-foaming agents and/or leveling agents, silane coupling agents such as imidazole-based compound, thiazole-based compound, and triazole-based compound, or any other known and commonly used additives.

The photocurable and thermosetting resin composition of the present invention having such a composition as described above is adjusted to a level of viscosity suitable for a particular coating method by dilution when necessary, then applied by the technique of screen printing, curtain coating, spray coating, roll coating, or the like to a printed circuit board having a circuit preparatorily formed thereon, and then dried at a temperature in the approximate range of 60 to 100° C., for example, to expel by evaporation the organic solvent contained in the composition to produce a coating film. The coating film is then selectively exposed to actinic radiation through a photomask having a prescribed exposure pattern and the unexposed area of the coating film is developed with an aqueous alkaline solution to form a resist pattern. The resist film formed in the prescribed pattern as described above is finally cured by irradiation with actinic energy rays and subsequent heating, or by heating and subsequent irradiation with actinic energy rays, or by heating only to give birth to a cured film (solder resist film) which exhibits low dielectric characteristics and excels in adhesiveness, resistance to electroless plating, electrical properties, flexibility, resistance to moisture absorption, and PCT (pressure cooker) resistance.

As an aqueous alkaline solution mentioned above, aqueous alkaline solutions of potassium hydroxide, sodium hydroxide, sodium carbonate, potassium carbonate, sodium phosphate, sodium silicate, ammonia, amines, etc. can be used.

Suitable light sources which are used for the purpose of photocuring the composition are a low-pressure mercury vapor lamp, a medium-pressure mercury vapor lamp, a high-pressure mercury vapor lamp, an ultra-high-pressure mercury vapor lamp, a xenon lamp, and a metal halide lamp, for example. Also, a laser beam may be used as the actinic energy rays.

When the photocurable and thermosetting resin composition of the present invention is used for the formation of an interlaminar insulating resin layer in a multi-layer printed circuit board, it is adjusted to a level of viscosity suitable for a particular coating method when necessary, then applied by a heretofore known method as described above onto a conductive layer of a printed circuit board having a circuit preparatorily formed thereon and, when necessary, dried at a temperature in the approximate range of 60 to 100° C., for example, to produce a tuck-free coating film. The coating film is then selectively exposed to actinic radiation through a negative film having a prescribed light impermeable pattern such as black circles and the unexposed areas of the coating film are developed, for example, with an aqueous alkaline solution as mentioned above to form via-holes corresponding to the black circles of the negative film. Thereafter, the formation of a through-hole such as a prescribed electrically conductive hole between layers is performed when necessary, the coating film is then subjected to a surface roughening treatment with a roughening agent such as an oxidizing agent, an aqueous alkaline solution, and an organic solvent. The surface of the insulating resin layer roughened is coated with a conductive layer by electroplating, electroless plating, etc. and then subjected to a heat treatment to increase the cross-linking density of the insulating resin layer mentioned above and simultaneously to effect the relaxation of stress. By curing the insulating resin layer by heating at a temperature in the approximate range of 140 to 180° C., for example, the interlaminar insulating resin layer excelling in various properties such as impact resistance, heat resistance, resistance to solvents, resistance to acids, resistance to moisture absorption, PCT resistance, adhesiveness, and electrical properties may be formed. Thereafter, a conductive layer of a circuit is formed by etching the surface of the conductive layer superposed on the surface of the insulating resin layer in a conventional manner to form a prescribed circuit pattern. Further, the insulating resin layers and the conductive layers of a prescribed circuit pattern may be alternately built up by repeating such steps one after another to a desired extent.

Incidentally, the photocurable and thermosetting resin composition of the present invention may be used not only as the insulating resin layer in a method of producing a multi-layer printed circuit board by the build-up process mentioned above but also, for example, in the formation of the insulating resin layer in a multi-layer printed circuit board by a lamination process with a copper foil provided with a resin and as an insulating resin composition for a prepreg to be used in the laminating press method.

Now, the present invention will be more specifically described below with reference to a working example and comparative examples. Wherever “parts” and “%” are mentioned hereinbelow, they invariably refer to those based on weight unless otherwise specified.

### SYNTHESIS EXAMPLE 1

Into a flask equipped with a gas introduction tube, a stirrer, a condenser, and a thermometer, 172 parts of 1,4-cyclohexene dicarboxylic acid and 880 parts of hydrogenated bisphenol A diglycidyl ether having an epoxy equivalent of 176 g/eq. (“YL-6663” manufactured by Japan Epoxy Resin K.K.) were charged and stirred at 100° C. under nitrogen atmosphere. Then, 0.65 part of triphenylphosphine was added to the mixture and the temperature in the flask was increased to 150° C. The reaction was continued for about 90 minutes while keeping the temperature at 150° C. to obtain an epoxy compound (A′) having an epoxy equivalent of 438 g/eq.

Next, the temperature in the flask was cooled to 70° C. or less, and 780 parts of epichlorohydrin and 635 parts of dimethyl sulfoxide were added to the mixture. The mixture was heated to 70° C. while stirring and kept at this temperature. Then, after 150 parts of 96% sodium hydroxide was dividually added to the mixture for 90 minutes, the reaction was continued for further 3 hours. After completion of the reaction, most of excess epichlorohydrin and dimethyl sulfoxide were distilled at 120° C. under a reduced pressure of 50 mmHg. The reaction product containing a by-product salt and dimethyl sulfoxide was dissolved in methyl isobutyl ketone and washed with water. Thereafter, methyl isobutyl ketone was recovered from the oil layer by distillation to obtain a polynuclear epoxy compound (A″) having an epoxy equivalent of 247 g/eq.

Next, in a flask equipped with a stirrer, a condenser, and a thermometer, 494 parts of the polynuclear epoxy compound (A″) and 400 parts of carbitol acetate added thereto were dissolved by heating. Then, 0.46 part of methylhydroquinone and 1.38 parts of triphenylphosphine were added to the solution. The resultant mixture kept heated to 95-105° C. and 350 parts of acrylic acid gradually added dropwise thereto were left reacting for 20 hours. The reaction product was cooled to 80-90° C. and made to add 300 parts of tetrahydrophthalic anhydride and they were left reacting for 8 hours. The reaction was followed up by the addition ratio obtained by the total acid value and the acid value of the reaction solution measured by potentiometric titration and the reaction ratio of 95% or more was regarded as the completion of the reaction.

The carboxyl group-containing actinic energy ray-curable resin consequently obtained was found to have an acid value of 89.2 mg KOH/g as solids. This reaction solution will be referred to hereinafter as “varnish A”. The infrared absorption spectrum (measured by using a Fourier-transform infrared spectrophotometer, FT-IR) of the carboxyl group-containing actinic energy ray-curable resin obtained in this synthesis example is shown in the attached drawing.

### COMPARATIVE SYNTHESIS EXAMPLE 1

In a flask equipped with a gas introduction tube, a stirrer, a condenser, and a thermometer, 330 parts of a cresol novolak type epoxy resin (EPICLON N-695, product of Dainippon Ink & Chemicals, Inc., epoxy equivalent; 220) and 400 parts of carbitol acetate added thereto were dissolved by heating. Then, 0.46 part of hydroquinone and 1.38 parts of triphenylphosphine were added to the solution. The resultant mixture kept heated to 95-105° C. and 108 parts of acrylic acid gradually added dropwise thereto were left reacting for 16 hours. The reaction product was cooled to 80-90° C. and made to add 163 parts of tetrahydrophthalic anhydride and they were left reacting for 8 hours. The reaction was followed up by the addition ratio obtained by the total acid value and the acid value of the reaction solution measured by potentiometric titration and the reaction ratio of 95% or more was regarded as the completion of the reaction. The carboxyl group-containing photosensitive resin consequently obtained was found to have an acid value of 100 mg KOH/g as solids. This reaction solution will be referred to hereinafter as “varnish B-1”.

### COMPARATIVE SYNTHESIS EXAMPLE 2

In a flask equipped with a gas introduction tube, a stirrer, a condenser, and a thermometer, 322 parts of a phenol novolak type epoxy resin (EPPN-201, product of Nippon Kayaku Co., Ltd., epoxy equivalent: 190) and 400 parts of carbitol acetate added thereto were dissolved by heating. Then, 0.46 part of hydroquinone and 1.38 parts of triphenylphosphine were added to the solution. The resultant mixture kept heated to 95-105° C. and 122 parts of acrylic acid gradually added dropwise thereto were left reacting for 16 hours. The reaction product was cooled to 80-90° C. and made to add 156 parts of tetrahydrophthalic anhydride and they were left reacting for 8 hours. The reaction was followed up by the addition ratio obtained by the total acid value and the acid value of the reaction solution measured by potentiometric titration and the reaction ratio of 95% or more was regarded as the completion of the reaction. The carboxyl group-containing photosensitive resin consequently obtained was found to have an acid value of 96 mg KOH/g as solids. This reaction solution will be referred to hereinafter as “varnish B-2”.

### EXAMPLE 1 AND COMPARATIVE EXAMPLES 1 AND 2

The components accounting for varying ratios of combination shown in Table 1 and using the varnishes obtained in the synthesis example 1 and comparative synthesis examples 1 and 2 mentioned above were severally kneaded with a three-roll mill to obtain photocurable and thermosetting resin compositions. The characteristics of these compositions are shown in Table 2.

TABLE 1

| Components | | | Comparative | Comparative |
|---|---|---|---|---|
| (parts by weight) | | Example 1 | Example 1 | Example 2 |
| Varnish | A | 100.0 | — | — |
| | B-1 | — | 100.0 | — |
| | B-2 | — | — | 100.0 |

| | | | |
|---|---|---|---|
| Irgacure 369*¹⁾ | 3.5 | 3.5 | 3.5 |
| Melamine | 2.0 | 2.0 | 2.0 |
| DPHA*²⁾ | 18.0 | 18.0 | 18.0 |
| EPICLON N-695*³⁾ | 30.0 | 33.0 | 31.0 |
| Barium sulfate | 50.0 | 50.0 | 50.0 |
| Phthalocyanine green | 1.0 | 1.0 | 1.0 |
| Carbitol acetate | 5.0 | 5.0 | 5.0 |

Remarks
*¹⁾Photopolymerization initiator produced by Ciba Speciality Chemicals Inc. 2-benzyl-2-dimethylamino-1-(4-morpholinophenyl)-butan-1-one
*²⁾Dipentaerythritol hexaacrylate
*³⁾Cresol novolak type epoxy resin produced by Dainippon Ink and Chemicals Inc.

TABLE 2

| | | | Comparative | Comparative |
|---|---|---|---|---|
| Properties | | Example 1 | Example 1 | Example 2 |
| Developing | 40 min. | ∘ | ∘ | ∘ |
| properties | 50 min. | ∘ | ∘ | ∘ |
| | 60 min. | ∘ | ∘ | ∘ |
| | 70 min. | ∘ | x | x |

| | | | |
|---|---|---|---|
| Tensile | 2.2 | 2.5 | 2.6 |
| modulus (Gpa) | | | |
| Tensile | 50 | 60 | 65 |
| strength (MPa) | | | |
| Elongation (%) | 6.0 | 2.5 | 3.0 |
| Water absorption (%) | 1.0 | 1.4 | 1.5 |
| Pencil hardness | 3H | 4H | 4H |
| Adhesiveness | ∘ | ∘ | ∘ |
| Dielectric constant | 3.2 | 3.5 | 3.6 |
| Dielectric dissipation | 0.020 | 0.028 | 0.029 |
| factor | | | |
| Electrical insulation | 2.0 | 1.3 | 1.5 |
| (× 10¹³ Ω) | | | |
| Resistance to acids | ∘ | ∘ | ∘ |
| Resistance to alkalis | ∘ | ∘ | ∘ |
| PCT resistance | ∘ | Δ | x |

The characteristics shown in Table 2 mentioned above were determined by the following methods.

(1) Developing Properties:

Each of the compositions of Example and Comparative Examples mentioned above was applied by a screen printing method to the entire surface of a copper foil plated-substrate having a prescribed pattern formed in advance thereon. The coating film on the substrate was dried for 40 minutes, 50 minutes, 60 minutes, or 70 minutes at 80° C. The coating film was left cooling to room temperature and then developed for 60 seconds with an aqueous 1% Na₂CO₃ solution of 30° C. applied by spraying at a pressure of 2.0 kg/cm². The residue of the dried coating film after development was visually examined. The criterion for evaluation is as follows:

◯: Development was perfect.

Δ: Part of the coating film remained.

X: The coating film remained completely.

(2) Tensile Modulus, (3) Tensile Strength (tensile strength at break), (4) Elongation (tensile elongation at break):

The tensile modulus, the tensile strength (tensile strength at break), and the elongation (tensile elongation at break) of the test samples produced by the following method were determined by a tensile and compression tester (manufactured by Shimadzu Seisakusho K.K.).

Each of the compositions of Example and Comparative Examples mentioned above was applied by the screen printing method to a polytetrafluoroethylene plate washed with water and dried in advance, and dried in a hot air circulating drying oven at 80° C. for 30 minutes. The composition on the plate was left cooling to room temperature and exposed to light under the conditions of irradiation dose of 100 mJ/cm², and then cured in a hot air circulating drying oven at 150° C. for 60 minutes. The cured film was left cooling to room temperature and then removed from the polytetrafluoroethylene plate to obtain a test sample.

(5) Water Absorption:

Each of the compositions of Example and Comparative Examples mentioned above was applied by the screen printing method to a glass sheet of which weight was measured in advance. The glass sheet covered with the composition was dried in a hot air circulating drying oven at 80° C. for 30 minutes. The composition on the sheet was left cooling to room temperature and exposed to light under the conditions of irradiation dose of 100 mJ/cm², and then cured in a hot air circulating drying oven at 150° C. for 60 minutes to obtain a test sample. The test sample was cooled to room temperature and then weighed. Subsequently, the test sample was treated for 24 hours in a PCT apparatus (TABAI ESPEC HAST SYSTEM TPC-412MD) under the conditions of 121° C., 100% R.H. and weighed to find the weight of the hardened product after the treatment. The water absorption of the hardened product was calculated by the following equation:

Water absorption (%)={(W2−W1)/(W1−Wg)}×100

where W1 is the weight of the test sample, W2 is the weight of the test sample after the PCT treatment, and Wg is the weight of the glass sheet.

Each of the compositions of Example and Comparative Examples mentioned above was applied by the screen printing method to a copper foil plated-substrate, and dried in a hot air circulating drying oven at 80° C. for 40 minutes. The composition on the substrate was left cooling to room temperature and exposed to light under the conditions of irradiation dose of 500 mJ/cm², cured in a hot air circulating drying oven at 150° C. for 60 minutes, and then left cooling to room temperature to obtain a test sample for the pencil hardness test and adhesiveness test.

(6) Pencil Hardness:

This hardness was determined by using a pencil hardness tester in accordance with method specified in JIS (Japanese Industrial Standard) K 5400 to obtain the highest hardness in which a film is not scratched when a load of 1 kg is applied to the sample mentioned above.

(7) Adhesiveness:

The cured film on the test sample mentioned above was incised like cross-cut and then subjected to a peeling test with an adhesive cellophane tape in accordance with the method specified in JIS D 0202. The degree of separation of the cured film after the peeling test was visually examined. The criterion for evaluation is as follows:

◯: Absolutely no peeling of the cured film observed.

Δ: Slight peeling of the cured film observed.

X: Complete peeling of the cured film observed.

(8) Dielectric Constant and Dielectric Dissipation Factor:

These characteristics were determined in accordance with the method specified in JIS C 6481.

(9) Electrical Insulating Properties:

Each of the compositions of Example and Comparative Examples mentioned above was applied to the entire surface of a comb electrode B coupon of IPC B-25 by using a roll coater manufactured by PILOT SEIKO K.K., and dried in a hot air circulating drying oven at 80° C. for 30 minutes. The composition on the substrate was left cooling to room temperature and exposed to light under the conditions of irradiation dose of 100 mJ/cm², cured in a hot air circulating drying oven at 150° C. for 60 minutes to obtain a test sample. The insulating resistance was measured by applying a bias voltage of DC 500V to the comb electrode.

(10) Acid Resistance Test:

This property was determined by keeping the same test sample as used in the test for electrical insulating properties (9) mentioned above immersed in an aqueous 10 vol. % sulfuric acid solution at 20° C. for 30 minutes, removing the test sample from the solution, and evaluating the test sample comprehensively with respect to the coating film condition and adhesiveness. The criterion for evaluation is as follows:

◯: Absence of discernible change

Δ: very slight presence of change

X: Occurrence of blister or swell or separation of coating film

(11) Alkali Resistance Test:

This property was determined by following the procedure of the acid resistance test (10) mentioned above except that an aqueous 10 vol. % sodium hydroxide solution was used in place of the aqueous 10 vol. % sulfuric acid solution.

(12) PCT Resistance:

Each of the compositions of Example and Comparative Examples mentioned above was applied by the screen printing method to a printed circuit board, and dried in a hot air circulating drying oven at 80° C. for 30 minutes. The composition on the board was left cooling to room temperature and exposed to light under the conditions of irradiation dose of. 100 mJ/cm², and then cured in a hot air circulating drying oven at 150° C. for 60 minutes to obtain a test sample. The test sample was left cooling to room temperature and then treated for 168 hours in the PCT apparatus (TABAI ESPEC HAST SYSTEM TPC-412MD) under the conditions of 121° C., 2 atmospheric pressure to evaluate the cured film condition. The criterion for evaluation is as follows:

◯: No discernible separation, discoloration, or dissolving out of the cured film observed.

Δ: Either of separation, discoloration, or dissolving out of the cured film observed.

X: Discernible separation, discoloration, or dissolving out of the cured film observed.

It is clearly noted from the results shown in Table 2 that the cured product obtained by using the photocurable and thermosetting resin composition of the present invention excelled not only in dielectric characteristics but also in such properties as water absorption, adhesiveness, electrical insulating resistance, hardness, resistance to chemicals, and PCT resistance. On the contrary, the cured products obtained by using the aromatic epoxy ester of an unsaturated monocarboxylic acids of the comparative examples were deficient in water absorption and PCT resistance.

While certain specific working examples have been disclosed herein, the invention may be embodied in other specific forms without departing from the spirit or essential characteristics thereof. The described examples are therefore to be considered in all respects as illustrative and not restrictive, the scope of the invention being indicated by the appended claims rather than by the foregoing description and all changes which come within the meaning and range of equivalency of the claims are, therefore, intended to be embraced therein.

What is claimed is:

1. An actinic energy ray-curable resin obtained by reacting (c) an epihalohydrin with hydroxyl groups of a linear epoxy resin (A′) which is a product of the polyaddition reaction of (a) a bifunctional hydrogenated bisphenolic epoxy compound having a hydrogenation degree of 0.1 to 100% with (b) a compound having at least two carboxyl groups in its molecule to obtain a polynuclear epoxy resin (A″) having epoxy groups in its terminal and side chain and further reacting (d) an unsaturated monocarboxylic acid with an epoxy group of said polynuclear epoxy resin to introduce a photopolymerizable unsaturated group therein and further reacting (e) a polybasic acid anhydride with a hydroxyl group of said polynuclear epoxy resin to introduce a carboxyl group therein.

2. The actinic energy ray-curable resin according to claim 1, wherein said polynuclear epoxy resin (A″) has the structure represented by the following general formula (2): 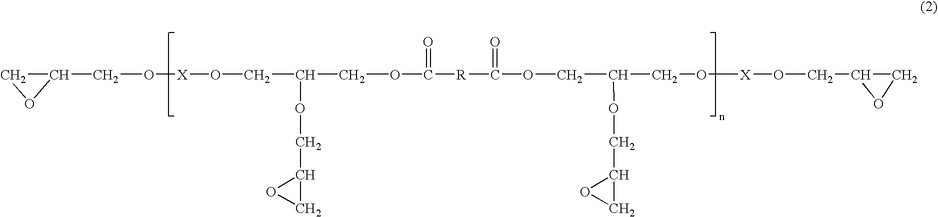
Wherein R represents a polycarboxylic compound residue, X represents at least one group represented by the following formulas, and n is an integer of not less than 1.

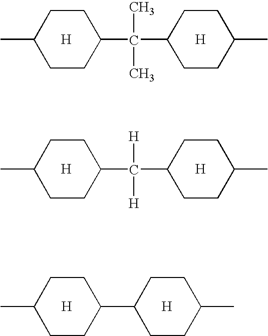

3. An actinic energy ray-curable resin obtained by reacting (c) an epihalohydrin with hydroxyl groups of a linear epoxy resin (A′) which is a product of the polyaddition reaction of (a) a bifunctional hydrogenated bisphenol A epoxy compound having a hydrogenation degree of 0.1 to 100% with (b) a compound having at least two carboxyl groups in its molecule to obtain a polynuclear epoxy resin (A″) having epoxy groups in its terminal and side chain and further reacting (d) an unsaturated monocarboxylic acid with an epoxy group of said polynuclear epoxy resin to introduce a photopolymerizable unsaturated group therein and further reacting (e) a polybasic acid anhydride with a hydroxyl group of said polynuclear epoxy resin to introduce a carboxyl group therein.

4. A photocurable and thermosetting resin composition capable of being developed with an aqueous alkaline solution, comprising (A) the actinic energy ray-curable resin set forth in claim 1, (B) a photopolymerization initiator, (C) a diluent, and (D) an epoxy compound containing at least two epoxy groups in its molecule.

5. The composition according to claim 4, which contains the photopolymerization initiator (B) in an amount of 0.1 to 25 parts by weight, the diluent (C) in an amount of 10 to 60 parts by weight, and the epoxy compound (D) having at least two epoxy groups in its molecule in an amount of 10 to 100 parts by weight, based on 100 parts by weight of said actinic energy ray-curable resin (A).

6. The composition according to claim 4, further comprising (E) an epoxy curing catalyst.

7. The composition according to claim 4, further comprising (F) a spherical porous filler having an average particle diameter of 1 to 10 μm.

8. The composition according to claim 4, further comprising (G) an actinic energy ray-curable resin other than said actinic energy ray-curable resin (A).

9. The composition according to claim 4, further comprising (H) an epoxidized polybutadiene.

10. The composition according to claim 4, further comprising (I) spherical urethane beads.

11. The composition according to claim 4, which is in the state of liquid.

12. The composition according to claim 4, which is in the form of a dry film.

13. A photocurable and thermosetting resin composition capable of being developed with an aqueous alkaline solution, comprising (A) the actinic energy ray-curable resin set forth in claim 3, (B) a photopolymerization initiator, (C) a diluent, and (D) an epoxy compound containing at least two epoxy groups in its molecule.

14. The composition according to claim 13, which contains the photopolymerization initiator (B) in an amount of 0.1 to 25 parts by weight, the diluent (C) in an amount of 10 to 60 parts by weight, and the epoxy compound (D) having at least two epoxy groups in its molecule in an amount of 10 to 100 parts by weight, based on 100 parts by weight of said actinic energy ray-curable resin (A).

15. The composition according to claim 13, further comprising (E) an epoxy curing catalyst.

16. The composition according to claim 13, further comprising (F) a spherical porous filler having an average particle diameter of 1 to 10 μm.

17. The composition according to claim 13, further comprising (G) an actinic energy ray-curable resin other than said actinic energy ray-curable resin (A).

18. The composition according to claim 13, further comprising (H) an epoxidized polybutadiene.

19. The composition according to claim 13, further comprising (I) spherical urethane beads.

20. The composition according to claim 13, which is in the state of liquid.

21. The composition according to claim 13, which is in the form of a dry film.

22. A cured product obtained by curing the photocurable and thermosetting resin composition set forth in claim 4 by means of irradiation of actinic energy rays and/or heating.

23. A cured product obtained by curing the photocurable and thermosetting resin composition set forth in claim 13 by means of irradiation of actinic energy rays and/or heating.

24. A printed circuit board having an interlaminar insulating layer and/or a solder resist layer formed from the photocurable and thermosetting resin composition set forth in claim 4.

25. A printed circuit board having an interlaminar insulating layer and/or a solder resist layer formed from the photocurable and thermosetting resin composition set forth in claim 13.
